(19) United States
(12) Patent Application Publication
(10) Pub. No.: US 2026/0298563 A1
(43) Pub. Date: Oct. 1, 2026

(54) COOLING APPARATUS AND SUBSTRATE PROCESSING APPARATUS

(71) Applicant: SCREEN Holdings Co., Ltd., Kyoto (JP)

(72) Inventors: Tomoaki AIHARA, Kyoto (JP); Tetsuya WATANABE, Kyoto (JP)

(21) Appl. No.: 19/569,417

(22) Filed: Mar. 17, 2026

(30) Foreign Application Priority Data
Mar. 25, 2025 (JP) 2025-049602

(51) Int. Cl. F28F 17/00

(52) U.S. Cl. CPC F28F 17/00

(57) ABSTRACT

A cooling apparatus according to the present invention includes a plurality of coolers each of which reduces a temperature of the processing liquid and a pipe along which the coolers are connected in series with each other, and a dew condensation management part which is configured to conduct independent dew condensation management on each of a plurality of blocks into which the flow path former is divided. It is possible to conduct the dew condensation management on each of the blocks of the flow path former including the plurality of coolers and the pipe. This allows the dew condensation management to be conducted effectively on the apparatus as a whole.

### CROSS REFERENCE TO RELATED APPLICATION

The disclosure of Japanese Patent Application No.2025-049602 filed on Mar. 25, 2025 including specification, drawings and claims is incorporated herein by reference in its entirety.

### BACKGROUND OF THE INVENTION

### 1. Field of the Invention

This invention relates to a technique of cooling and outputting a processing liquid to be used in processing a substrate, for example.

### 2. Description of the Related Art

In a process of manufacturing various kinds of substrates such as semiconductor substrates or glass substrates, for example, processing liquids at various temperatures having various compositions are used for processing the substrates. In some cases, water prepared by cooling high-purity water such as de-ionized water or pure water to a temperature around its freezing point (0° C.) (resultant water is simply called “cool water” herein) is required to be used as these processing liquids. As an example, according to a technique shown in JP2024-134431A (Patent Literature 1) disclosed previously by the applicant of the present application, de-ionized water (DIW) temperature-regulated to a low temperature is used as a cooling medium and brought into contact with a back surface of a substrate for the purpose of cooling the substrate heated during a course of a process.

In an apparatus for generating a processing liquid cooled in this way, an atmosphere around a member such as a pipe for causing the processing liquid at a low temperature to flow therethrough is also cooled, so that water droplets resulting from dew condensation may be caused in an environment where the apparatus is installed. In particular, if a cooling target temperature of the processing liquid is approximate to 0° C. as a freezing point of water, dew condensation may be caused with an extremely high probability. Such dew condensation may be avoided, for example, by taking a measure such as covering a cooling apparatus entirely with a heat-insulating member or causing a low dew-point gas, e.g. dry gas, to always flow in a housing of the cooling apparatus.

However, when the cooling apparatus is viewed as a whole, many parts are free from the risk of dew condensation, or in some parts, dew condensation itself may cause no problem even if it occurs. For this reason, taking the above measure against dew condensation in the apparatus as a whole cannot be said to be always effective but rather, it might result in excessive equipment to cause increase in apparatus cost. Patent Literature 1 does not provide particular statement of a supply source of cool water and thus it does not provide mention about a measure against resultant dew condensation.

### SUMMARY OF THE INVENTION

This invention has been made in view of the above problem, and allows implementation of an effective measure against dew condensation in a cooling apparatus configured to cool and output a processing liquid.

One aspect of the present invention is intended for a cooling apparatus configured to cool and output a processing liquid, comprising: a flow path former including a plurality of coolers each configured to reduce the temperature of the processing liquid and a pipe along which the coolers are connected in series with each other, and forming a flow path of the processing liquid; and a dew condensation management part configured to conduct independent dew condensation management on each of a plurality of blocks into which the flow path former is divided.

According to the invention thus configured, the flow path former including the cooler for cooling the processing liquid and the pipe for causing the processing liquid to pass therethrough is divided into the plurality of blocks, and the dew condensation management is conducted on each of the blocks. This allows the dew condensation management to be conducted in different ways in units of the blocks, for example, so that various measures can be taken on the corresponding blocks in response to a situation of the occurrence of dew condensation or purpose of use. As a result, it is possible to conduct the more effective dew condensation management than in a case where a measure against dew condensation is taken on the apparatus as a whole. The dew condensation management mentioned herein is an idea that covers not only prevention of the occurrence of dew condensation but also management of the amount of water droplets resulting from dew condensation, and permission of the occurrence of dew condensation itself and then avoidance of adverse influence on the apparatus due to the dew condensation.

In particular, in the presence of the plurality of series-connected coolers to reduce the temperature of the processing liquid, the temperature of the processing liquid is reduced stepwise by these coolers to increase the probability of the occurrence of dew condensation correspondingly. Thus, a difference is generated in probability of the occurrence of dew condensation between the cooler on an upstream side and the cooler on a downstream side. For this reason, a process suitable as a measure against dew condensation is considered not to be uniform. Even in such a situation, the present invention allows application of a measure against dew condensation responsive to each of the coolers.

Another aspect of the present invention is intended for a substrate processing apparatus comprising: a cooling part having the same configuration as the above cooling apparatus; a substrate processor configured to process a substrate using the processing liquid output from the cooling part; and a supply pipe configured to supply the processing liquid from the cooling part to the substrate processor. According to the invention thus configured, the cooled processing liquid is supplied to the substrate processor from the cooling part where the dew condensation management has been conducted in the way described above, and the substrate processor can process a substrate favorably using the supplied processing liquid.

As described above, according to the present invention, it is possible to conduct the dew condensation management on each of the blocks of the flow path former including the plurality of coolers and the pipe. This allows the dew condensation management to be conducted effectively on the apparatus as a whole.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 shows a schematic configuration of a substrate processing system according to a first embodiment of the present invention;

FIG. 2 shows an exemplary configuration of a cooling unit;

FIGS. 3A to 3C show an exemplary configuration of a heat exchanger;

FIGS. 4A and 4B schematically show temperature change in the processing liquid along a flow path;

FIG. 5 schematically shows a dew condensation management according to a present embodiment; and

FIG. 6 shows a schematic configuration of a second embodiment of a substrate processing system including a cooling apparatus according to the present invention.

### DETAILED DESCRIPTION OF THE PREFERRED EMBODIMENTS

### First Embodiment

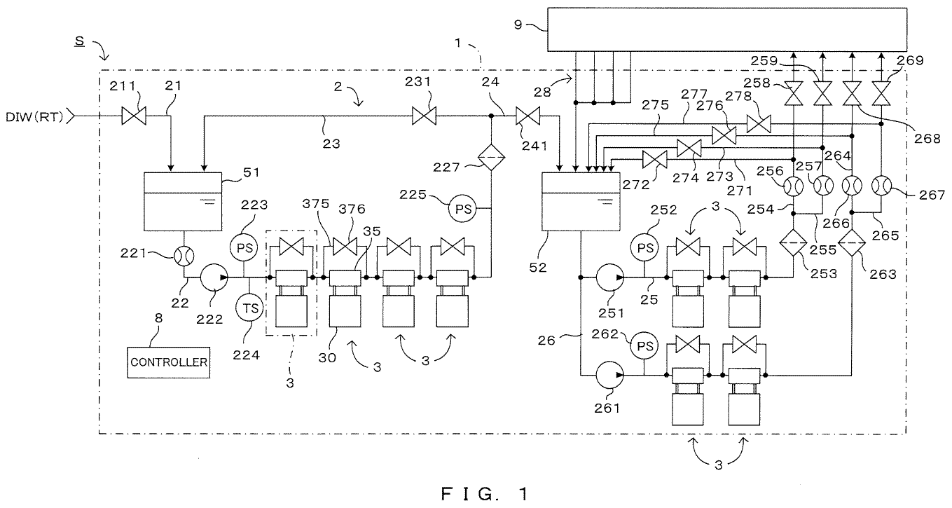

FIG. 1 shows a schematic configuration of a substrate processing system according to a first embodiment of the present invention. This substrate processing system S includes a processing liquid supplier 1 and a substrate processor 9. The processing liquid supplier 1 cools pure water or de-ionized water supplied from an external supply source to a predetermined temperature and outputs the cooled water as a processing liquid. The substrate processor 9 processes a processing target substrate using the processing liquid supplied from the processing liquid supplier 1. In the following, DIW will be described as a representative of the processing liquid. The substrate processor 9 may be configured to supply this processing liquid as it is to the substrate, or may be configured to mix the processing liquid with a different type of chemical or an organic solvent such as isopropyl alcohol (IPA) and supply a resultant liquid to the substrate, for example. While a semiconductor wafer is applicable as the substrate to be processed, for example, the substrate is not limited to this. While a representative process by the substrate processor 9 includes a rinsing process, wet cleaning, and wet etching performed by supplying a processing liquid, a chemical or the like to the substrate, it is not particularly limited.

The processing liquid supplier 1 includes a pipe system 2 for supplying the DIW to the substrate processor 9. Various types of functional units are provided appropriately along the piping to form a flow path of the processing liquid. More specifically, a control valve 211 is interposed in a pipe 21 connected to an external DIW supply source, and a terminal of the pipe 21 is connected to a primary reservoir tank 51. When the control valve 211 is opened in response to a control command from a controller 8 responsible for control over the behavior of the device as a whole, the DIW at room temperature (RT) supplied from the outside flows into the primary reservoir tank 51 through the pipe 21.

In the following, terms “flow direction,” “upstream side,” and “downstream side” are used for defining positions along a flow path of the processing liquid or a cooling medium. Unless specified otherwise, these terms show a flow direction of a liquid at a corresponding position along the flow path, and an upstream side and a downstream side of this flow direction.

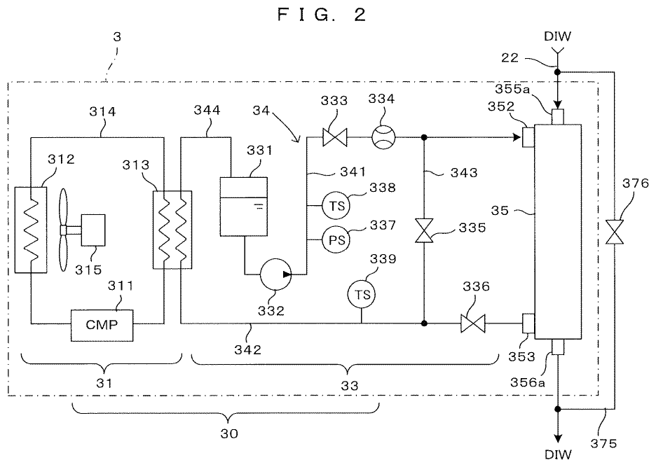

A pipe 22 is connected to a lower part of the primary reservoir tank 51. A flowmeter 221, a feed pump 222, a pressure sensor 223, a temperature sensor 224, four cooling units 3, a pressure sensor 225, a filter 227, and the like are connected to the pipe 22. Each of these functional units may be added appropriately, as needed, to a position other than the illustrated position, or some of these functional units may be omitted. As an example, pressure reduction between the upstream side (primary side) and the downstream side (secondary side) with respect to a heat exchanger 35 (FIG. 2) disposed to the cooling unit 3 caused by pressure loss at the heat exchanger 35 can be acquired as data or can be calculated through experiment or simulation conducted previously. Thus, in one configuration, the pressure sensor 225 on the downstream side with respect to the heat exchanger 35 may be omitted.

Each of the flowmeter 221 and flowmeters described later detects the flow rate of a liquid in a flow path. Each of the feed pump 222 and feed pumps described later feeds a liquid supplied from the upstream side of the flow path toward the downstream side. Each of the pressure sensor 225 and pressure sensors described later detects the pressure of the liquid in the flow path. Each of the temperature sensor 224 and temperature sensors described later detects the temperature of the liquid in the flow path.

Each of the flowmeters, the feed pumps, the pressure sensors, and the temperature sensors is communicably connected to the controller 8. An output signal from each of the flowmeters, the pressure sensors, and the temperature sensors is transmitted to the controller 8. Each feed pumps and each control valves described later operate in response to a control command from the controller 8 to regulate the flow of the processing liquid in the flow path. The controller 8 controls the behaviors of movable parts including the feed pumps and the control valves in response to a control program prepared in advance and signals transmitted from sensors including the flowmeters, the pressure sensors, and the temperature sensors.

The cooling unit 3 has the function of reducing the temperature of an incoming liquid and outputting the resultant liquid. A final temperature of the processing liquid to be output from the cooling unit 3 is not particularly limited. Meanwhile, the final temperature may be set to a temperature lower than room temperature and slightly higher than 0° C. as a freezing point of the DIW, for example, and may be set to 5° C., for example. The number of the cooling units 3 may be one. Meanwhile, in order to reduce the temperature of the processing liquid supplied at room temperature efficiently in shorter time to a target temperature, two or more cooling units 3 may be connected in series with each other, for example. In an example shown in FIG. 1, four cooling units 3 are disposed to the processing liquid supplier 1. In order to increase the quantity of the processing liquid to be cooled, two or more cooling units 3 may be connected in parallel. The cooling unit 3 will be described later in detail.

The pipe 22 branches on the downstream side with respect to the filter 227 into a pipe 23 and a pipe 24. A control valve 231 is interposed in the pipe 23, and a terminal of the pipe 23 is connected to the primary reservoir tank 51. Specifically, the pipes 22 and 23 function as a circulation flow path of causing the processing liquid to circulate with respect to the primary reservoir tank 51. As the feed pump 222 for feeding the processing liquid under pressure and the cooling unit 3 for cooling the processing liquid are interposed in the pipe 22, the processing liquid circulates through the circulation flow path to maintain the processing liquid in the primary reservoir tank 51 at a predetermined temperature lower than room temperature.

A control valve 241 is interposed in the other pipe 24, and a terminal of the pipe 24 is connected to a secondary reservoir tank 52. The cooled processing liquid passed through the pipe 24 flows into the secondary reservoir tank 52, and the secondary reservoir tank 52 stores the processing liquid therein.

Two-system pipes 25 and 26 are connected to a lower part of the secondary reservoir tank 52. A feed pump 251, a pressure sensor 252, the cooling unit 3, a filter 253, and the like are interposed in the pipe 25. Two cooling units 3 are connected in series. In addition to these units, functional units may be added appropriately, as needed, such as a flowmeter, a temperature sensor, and a pressure sensor, or some of the above units may be omitted. The feed pump 251 feeds the processing liquid supplied from the secondary reservoir tank 52 toward the downstream side under pressure. The fed processing liquid is temperature-regulated to a final target temperature (in this example, 5° C.) by the two series-connected cooling units 3.

The pipe 25 branches into two pipes 254 and 255 on the downstream side with respect to the filter 253. A flowmeter 256 and a control valve 258 are interposed in the pipe 254, and the pipe 254 is finally connected to the substrate processor 9. A flowmeter 257 and a control valve 259 are interposed in the pipe 255, and the pipe 255 is finally connected to the substrate processor 9. That is, the pipes 254 and 255 each have a function as a feed pipe for feeding the processing liquid to the substrate processor 9.

Likewise, a feed pump 261, a pressure sensor 262, the cooling unit 3, a filter 263, and the like are interposed in the pipe 26. In addition to these units, functional units may be added appropriately, as needed, such as a flowmeter, a temperature sensor, and a pressure sensor, or some of the above units may be omitted. The feed pump 261 feeds the processing liquid supplied from the secondary reservoir tank 52 toward the downstream side under pressure. The fed processing liquid is temperature-regulated to the final target temperature by the two series-connected cooling units 3.

The pipe 26 branches into two pipes 264 and 265 on the downstream side with respect to the filter 263. A flowmeter 266 and a control valve 268 are interposed in the pipe 264, and the pipe 264 is finally connected to the substrate processor 9. A flowmeter 267 and a control valve 269 are interposed in the pipe 265, and the pipe 265 is finally connected to the substrate processor 9. Specifically, each of the pipes 264 and 265 also has a function as a feed pipe for feeding the processing liquid to the substrate processor 9.

As described above, the processing liquid supplier 1 of this embodiment includes the four-system feed pipes provided for the substrate processor 9 and allowing respective flow rates to be regulated therein independently of each other. This allows the processing liquid supplier 1 to supply the cooled processing liquid (DIW) to four substrate processing units provided in the substrate processor 9. In the case of a different number of the substrate processing units, the number of the feed pipes can be increased or reduced in conformity with the number of the substrate processing units.

A bypass pipe 271 branches from the pipe 254, and a terminal of the bypass pipe 271 is connected to the secondary reservoir tank 52. A control valve 272 is interposed in the bypass pipe 271. Likewise, bypass pipes 273, 275, and 277 branch from the pipes 255, 264, and 265 respectively, and respective terminals of these bypass pipes are connected to the secondary reservoir tank 52. Control valves 274, 276, and 278 are interposed in the bypass pipes 273, 275, and 277 respectively. The bypass pipes 271, 273, 275, and 277 have the function of flowing the DIW not to be fed to the substrate processor 9 back into the secondary reservoir tank 52.

The substrate processor 9 and the secondary reservoir tank 52 are connected to each other through four-system pipes (return pipes) 28. The processing liquid returning from each substrate processing unit in the substrate processor 9 flows into the secondary reservoir tank 52 through the pipe 28. In this way, the four-system feed pipes independent of each other and the four-system return pipes independent of each other are provided between the processing liquid supplier 1 and the substrate processor 9 as flow paths for causing the processing liquid to flow therebetween.

The pipes and the functional units forming the pipe system 2 are each made of a resin material in a part to contact the processing liquid. As an example, fluorine resin such as perfluoroalkoxy alkane (PFA) resin or polytetra fluoroethylene (PTFE) resin is preferably applicable as a material not to cause release of impurity such as metal ions into the processing liquid.

FIG. 2 shows an exemplary configuration of the cooling unit. All the cooling units 3 provided along the pipe system 2 are based on the same principles. Meanwhile, the sizes (capacities) and cooling performances thereof are not always required to be the same but can be selected, as appropriate, in response to the temperature and flow rate of the processing liquid to be handled by each of the cooling units 3.

The cooling unit 3 includes a cooling medium output part 30 (a refrigerating circuit 31 and a circulating liquid circuit 33) and a heat exchanger 35 as main structures. A circuit already available as a product can be used as the refrigerating circuit 31. Thus, only a minimum configuration required for explanation of principles is shown in the drawings and the operation thereof will be described simply. Further, regarding a pressure sensor and a temperature sensor appropriately provided along the flow path as necessary, descriptions of these sensors will also be omitted.

In the cooling unit 3, a first cooling medium cooled by the refrigerating circuit 31 is used to cool a second cooling medium to circulate in the circulating liquid circuit 33, and the heat exchanger 35 cools the processing liquid using the second cooling medium thereby cooled. By doing so, the processing liquid is cooled to a desired cooling target temperature. Cooling the processing liquid in this way by the two-stage cooling process using the intervening circulating liquid circuit 33 is intended to eliminate metal to become a contamination source from the pipes and the like to be touched by the DIW as the processing liquid, thereby outputting high-purity DIW.

The refrigerating circuit 31 is a so-called chiller, and includes a compressor (compression machine) 311, an air-cooled condenser 312, an evaporator 313, and a pipe 314 connecting these parts to form a circulation flow path. An appropriate cooling medium (first cooling medium) that may be chlorofluorocarbons or a substitute for chlorofluorocarbons, for example, is poured under a high pressure in the circulation flow path. The cooling medium compressed and pressurized by the compressor 311 and the air-cooled condenser 312 is vaporized by the evaporator 313. During the vaporization, heat is drawn from the surrounding to cool a target. Here, a cooling target is the second cooling medium poured in the circulating liquid circuit 33.

A fan motor 315 is arranged near the air-cooled condenser 312, and dissipates heat of condensation generated by the first cooling medium to the outside. While not shown in the drawings, functional units including an expansion valve, a pressure sensor, and a temperature sensor are provided at appropriate positions in the refrigerating circuit 31.

The circulating liquid circuit 33 feeds the cooling medium (second cooling medium) having been cooled by the refrigerating circuit 31 to the heat exchanger 35 in the next stage. For this purpose, the circulating liquid circuit 33 has a configuration where a reservoir tank 331, a feed pump 332, control valves 333, 335, and 336, a flowmeter 334 and the like are interposed in a pipe 34. More specifically, the pipe 34 includes a pipe 341 forming connection between a lower part of the reservoir tank 331 and an input port 352 of the heat exchanger 35, a pipe 342 forming connection between an output port 353 of the heat exchanger 35 and the evaporator 313, a pipe 343 forming connection between the pipe 341 and the pipe 342, and a pipe 344 forming connection between the evaporator 313 and the reservoir tank 331.

The feed pump 332, the control valve 333, and the flowmeter 334 are interposed in the pipe 341. The control valve 336 is interposed in the pipe 342. The pipe 343 is provided in such a way as to form connection between the downstream side of the pipe 341 with respect to the flowmeter 334 and the downstream side of the pipe 342 with respect to the control valve 336, and the control valve 335 is provided along a flow path in the pipe 343.

When the feed pump 332 feeds the cooling medium under pressure and the control valve 333 is opened in response to a control command from the controller 8, the cooling medium fed from the reservoir tank 331 is supplied to the heat exchanger 35. By opening the control valve 336, the cooling medium returning from the heat exchanger 35 is allowed to be received in the pipe 342. By opening the control valve 335, the cooling medium fed by the feed pump 332 is allowed to flow at least partially or entirely into the pipe 342 while bypassing the heat exchanger 35.

The cooling medium having flowed into the pipe 342 from the heat exchanger 35 and the pipe 343 flows back into the reservoir tank 331 through the evaporator 313 and the pipe 344. In this way, a flow path for causing the cooling medium (second cooling medium) to circulate from the reservoir tank 331 through the evaporator 313 is formed in the circulating liquid circuit 33. The second cooling medium cooled by the evaporator 313 circulates in the circulating liquid circuit 33. As a result, the temperature of the circulating cooling medium is stabilized.

A pressure sensor 337 and a temperature sensor 338 are provided on the downstream side of the pipe 341 with respect to the feed pump 332. An additional temperature sensor 339 is provided on the downstream side of the pipe 342 with respect to a point of merging with the pipe 343. The controller 8 controls the feed pump 332 and the control valves 333, 335 and 336 on the basis of output signals from these sensors, thereby feeding the cooling medium at a predetermined temperature and a predetermined flow rate into the heat exchanger 35.

A liquid to be used as the second cooling medium is a liquid coolable to a lower temperature than a final cooling target temperature of the processing liquid (in this example, 5° C. and this temperature will be called a “final target temperature”) without being coagulated by freezing. For example, ethylene glycol (EG) having a melting point of minus 13° C. or an aqueous solution thereof is preferably available. Regarding the temperature of the second cooling medium, the second cooling medium is maintained at a lower temperature than the target temperature of the processing liquid to be output from the cooling unit 3.

As will be described later in detail, the heat exchanger 35 includes an input port 355a for DIW for receiving the processing liquid (DIW) to be cooled, an output port 356a for outputting the cooled DIW, the input port 352 for cooling medium for receiving the second cooling medium, and the output port 353 for discharging the cooling medium. The DIW to be cooled is input to the input port 355a, and the DIW cooled through heat exchange with the cooling medium is output from the output port 356a.

A pipe 375 for bypassing the heat exchanger 35 and a control valve 376 interposed in the pipe 375 are provided, as external parts not belonging to constituting parts of the cooling unit 3, between the input port 355a and the output port 356a of the heat exchanger 35. As will be described later, opening the control valve 376 as needed allows the heat exchanger 35 to be bypassed. If the temperature of the DIW to be input is already lower than a target temperature, for example, it is possible to avoid further temperature reduction by bypassing the heat exchanger 35.

As needed, two or more cooling unit 3 thus configured are provided along the flow path. In this embodiment, four cooling units 3 are connected in series along the pipe 22. Two cooling units 3 are further connected in series along each of the pipes 25 and 26 respectively.

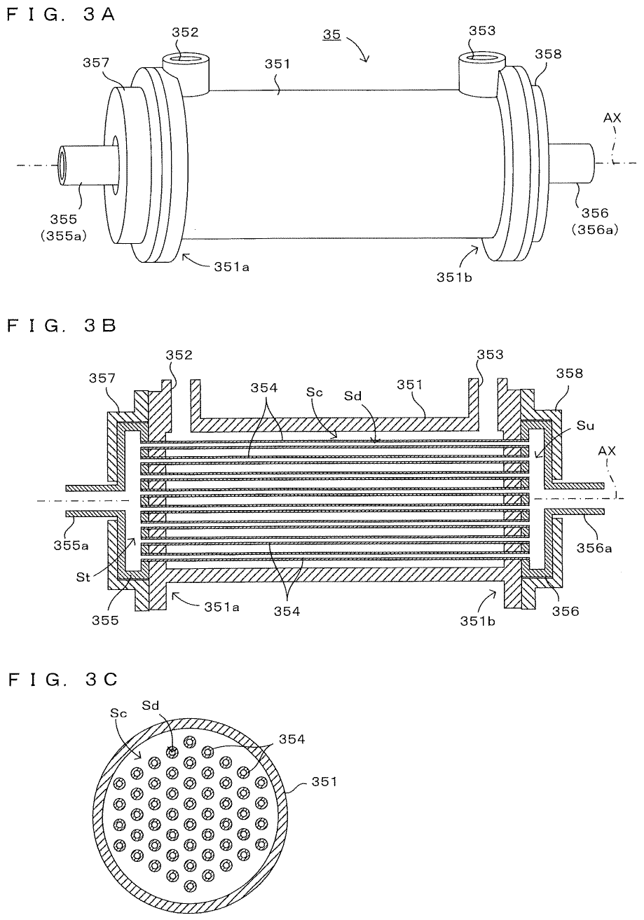

FIGS. 3A to 3C show an exemplary configuration of the heat exchanger. More specifically, FIG. 3A shows the appearance of the heat exchanger 35. In FIG. 3A, a dash-dot line shows a virtual center axis AX of the heat exchanger 35. FIG. 3B is a longitudinal sectional view showing a section of the heat exchanger 35 along the center axis AX. FIG. 3C is a cross sectional view showing a section perpendicular to the center axis AX.

The heat exchanger 35 includes a housing 351 having a substantially circular columnar outer shape with a hollow interior extending along the center axis AX, in other words, having a circular cylindrical shape with closed opposite ends. The housing 351 has a side surface where the input port 352 is provided at a position close to one edge 351a of the housing 351, and the output port 353 is provided at a position close to the other edge 351b of the housing 351 opposite to the one edge 351a. The cooling medium fed from the circulating liquid circuit 33 flows through the input port 352 into an internal space defined by an inner wall of the housing 351, and flows out through the output port 353. The cooling medium having flowed into the internal space of the housing 351 fills an external side of an inner pipe inserted in and passed through the internal space and used for causing the DIW to flow therein. In the internal space of the housing 351, a space except the inner pipe and except a space in the inner pipe is called a current space Sc. The cooling medium supplied from the circulating liquid circuit 33 to the heat exchanger 35 flows in the current space Sc.

The housing 351 includes a plurality of inner pipes 354 inserted in and passed through the housing 351 and penetrating the current space Sc from the one edge 351a to the other edge 351b of the housing 351. On the side of the one edge 351a, the inner pipe 354 is terminated by a terminal member 355 and an internal space Sd of the inner pipe 354 communicates with an internal space St of the terminal member 355. Likewise, on the side of the other edge 351b, the inner pipe 354 is terminated by a terminal member 356 and the internal space Sd of the inner pipe 354 communicates with an internal space Su of the terminal member 356. As a result, the respective internal spaces St and Su of the terminal members 355 and 356 communicate with each other via the internal space Sd of the inner pipe 354.

An input port 355a for receiving the DIW to be cooled is provided at an end of the terminal member 355. An output port 356a for feeding the DIW is provided at an end of the terminal member 356. The input port 355a connects to one end of each of the inner pipes 354, and the other end of each inner pipe 354 connects to the output port 356a. Thus, the inner pipes 354 have a parallel relationship with each other in terms of a flow path of the DIW. The DIW having flowed into the internal space St from the input port 355a branches into flows to enter the inner pipes 354, passes through the internal space Sd of each inner pipe 354 to flow out into the internal space Su, and is then fed through the output port 356a toward the downstream side with respect to the heat exchanger 35. Specifically, the terminal member 355 and the inner pipes 354 function as a manifold for branching the DIW, and the inner pipes 354 and the terminal member 356 function as a manifold for merging the flows of the DIW.

In the following, if the input port 355a and the input port 352 are required to be distinguished from each other, they will be called an “input port 355a for DIW” and an “input port 352 for cooling medium.” Likewise, if the output port 356a and the output port 353 are required to be distinguished from each other, they will be called an “output port 356a for DIW” and an “output port 353 for cooling medium.”

The inner pipe 354 and the terminal members 355 and 356 are made of resin materials not to cause release of impurity such as metal ions. Like the other pipes, the inner pipe 354 and the terminal members 355 and 356 are formed by using a material that is preferably a fluorine resin material such as PFA resin, for example. As an example, a PFA tube is available as the inner pipe 354. Regarding the terminal members 355 and 356 each required to be processed into a complicated shape, PTFE resin is available in addition to PFA resin. The terminal members 355 and 356 can be formed into the same shape.

The terminal members 355 and 356 are fixed to the housing 351 by cover members 357 and 358 respectively. Specifically, the terminal member 355 is mounted on the one edge 351a of the housing 351 in such a way as to be interposed between the one edge 351a of the housing 351 and the cover member 357. Likewise, the terminal member 356 is mounted on the other edge 351b of the housing 351 in such a way as to be interposed between the other edge 351b of the housing 351 and the cover member 358. The cover members 357 and 358 can be formed into the same shape.

The housing 351 and the cover members 357 and 358 are each made of metal such as stainless steel, for example, and are coupled to each other with coupling members such as bolts not shown in the drawings. As will be described later, while each of the cooling medium and the DIW is supplied to the heat exchanger 35 in a pressurized state, forming the housing 351 using solid metal provides resistance to such a pressure. The resin terminal members 355 and 356 themselves do not have high resistances to such a pressure. However, reinforcing the terminal members 355 and 356 from outside using the cover members 357 and 358 allows the terminal members 355 and 356 to be resistant to such a pressure.

The current space Sc and the internal space Sd of the inner pipe 354 are separated from each other by a pipe wall of the inner pipe 354, and the cooling medium flowing in the current space Sc and the DIW flowing in the internal space Sd are separated from each other. An outer surface of the pipe wall touches the cooling medium at a low temperature. Thus, the DIW is cooled through heat exchange with the cooling medium across the pipe wall, and is output from the output port 356a at a lower temperature than the temperature of the DIW during input from the input port 355a. As the inner pipes 354 are inserted in and passed through the interior of the housing 351, the DIW is cooled at high efficiency. Here, the cooling medium and the DIW flow in the same direction (in FIG. 3A, toward the right) in the heat exchanger 35. Meanwhile, the flow direction of the cooling medium and the flow direction of the DIW may be reversed by switching the input and output of the cooling medium, for example.

If the cooling units 3 are connected in multiple stages, a cooling target temperature at each cooling unit 3 is not required to be the final target temperature. Specifically, in a configuration of bringing the DIW to the final target temperature stepwise using the cooling units 3 in multiple stages, a temperature reduction required to be attained in each cooling unit 3 can be smaller. In this case, each of the temperature of the DIW to be input and the temperature of the DIW to be output differs between the cooling devices 3, so that the cooling units 3 are not always required to be the same in terms of respective configurations and specifications.

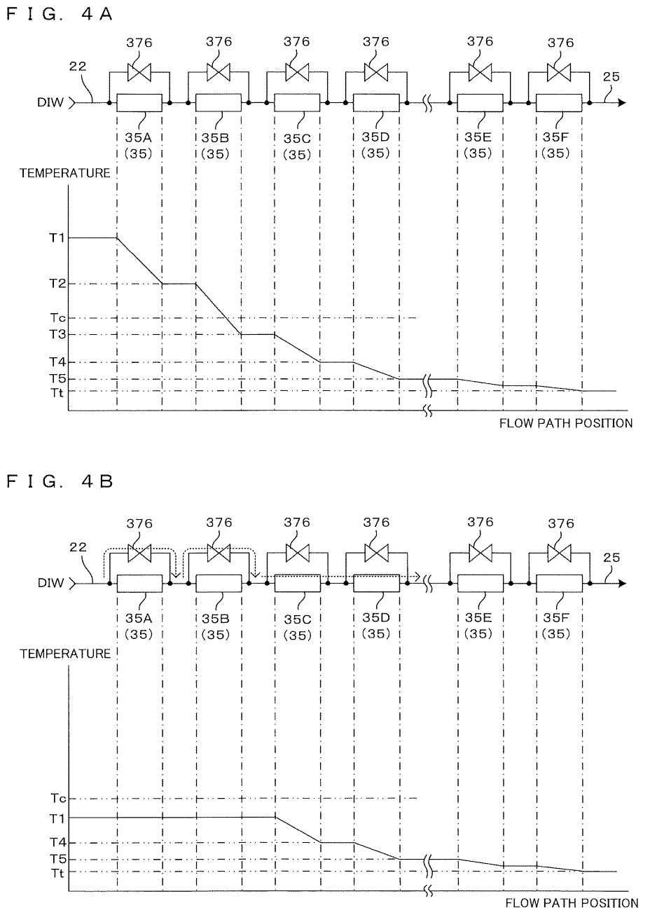

A specific configuration of temperature regulation on the processing liquid using the cooling unit 3 will be described next. For explanation of principles, a temperature regulating method implemented in the single cooling unit 3 will be described by referring to FIGS. 4A and 4B. A flow descried herein is such that the DIW supplied from an external supply source through the pipe 21 is cooled by the plurality of cooling units 3 and then output through the pipe 25. This idea is also applicable to the DIW to be output through the pipe 26.

FIGS. 4A and 4B schematically show temperature change in the processing liquid along the flow path. As shown in the upper view of FIG. 4A, at the processing liquid supplier 1, six heat exchangers 35 are connected in series along the flow path of the DIW, and the temperature of the DIW is reduced each time the DIW passes through the heat exchanger 35. In the following, if these heat exchangers 35 are required to be distinguished from each other, they will be given signs 35A, 35B, . . . , 35F in this order from the upstream side.

The graph in the lower view of FIG. 4A shows a temperature distribution along the flow path determined when the DIW of a substantially constant quantity is output to the substrate processor 9 and the DIW of a quantity substantially equal to the output quantity is always added from the outside in order to compensate for the output DIW. Here, temperature increase of the DIW accompanying flow of the DIW is considered ignorable. The DIW at a temperature T1 output from the primary reservoir tank 51 is cooled to a temperature T2 by passing through the first heat exchanger 35A. Likewise, the DIW are reduced to temperatures T3, T4, and T5 by passing through the heat exchangers 35B, 35C, and 35D respectively. These temperatures T2 and T5 can be set in advance as cooling target temperatures for the heat exchangers 35A to 35D respectively.

The temperature T5 assumes a value approximate to a final target temperature Tt at the time of feed to the substrate processor 9. The DIW cooled to the temperature approximate to the final target temperature Tt in this way is supplied to the secondary reservoir tank 52. Thus, the heat exchangers 35E and 35F provided between the secondary reservoir tank 52 and the substrate processor 9 are simply required to perform cooling for maintaining the DIW at the final target temperature Tt sufficiently cooled in advance.

As described above, the temperature of the DIW is reduced stepwise using the heat exchangers 35 connected in series at multiple stages, and the heat exchanger 35F at the final stage only conducts fine regulation. By doing so, the temperature of the DIW to be output is allowed to reach the final target temperature Tt stably. With the final target temperature Tt (5° C.) approximate to a freezing point (0° C.) of the processing liquid (DIW) like in this embodiment, freezing of the processing liquid might occur if the temperature of the output processing liquid fluctuates to fall below the freezing point even if only temporarily. Large temperature fluctuation is prevented by performing cooling at multiple stages using the plurality of heat exchangers 35 connected in series and setting a small temperature regulation range at the heat exchanger 35 on the downstream side, making it possible to prevent the processing liquid from being coagulated by freezing before it occurs.

The temperatures T1 to T5 of the DIW are not always constant. The heat exchangers 35A to 35D are arranged in the circulation flow path configured using the pipes 22 and 23. Thus, the temperature T1 of the DIW to be input to the most-upstream heat exchanger 35 assumes an intermediary value between the temperature of the DIW stored in the primary reservoir tank 51 and the temperature of the DIW supplied from the outside through the pipe 21.

At an initial stage such as a moment of start-up of the apparatus, the temperature of the DIW in the primary reservoir tank 51 is room temperature, for example, so that the temperature T1 also assumes a value approximate to room temperature. As a result of the high temperature of the DIW to be input, the temperatures T2 to T5 of the DIW output from the corresponding heat exchangers 35 might also become higher than their target temperatures. If the temperature T5 of the DIW output from the heat exchanger 35D is higher than the target temperature, the control valve 231 is opened and the control valve 241 is closed. This causes the DIW to flow back into the primary reservoir tank 51 through the pipe 23 and restricts output to the secondary reservoir tank 52. As a result, temperature increase of the DIW stored in the secondary reservoir tank 52 is prevented.

Conversely, if the temperature of the DIW in the primary reservoir tank 51 is reduced by causing the DIW to circulate while cooling the DIW, the temperature T1 is also reduced. This also reduces the temperatures T2 to T5 of the DIW output from the corresponding heat exchangers 35 to be approximated further to their target temperatures. In some cases, these temperatures might become lower than the target temperatures. A temperature regulating method implemented in this case will be described later by referring to FIG. 4B.

In the drawing, a temperature Tc indicates a dew-point temperature of indoor air in an environment where the processing liquid supplier 1 is installed. During a course of cooling the DIW from a temperature around room temperature to a temperature around 0° C., the temperature of the DIW is highly likely to change across the dew-point temperature Tc. In a stationary state where the DIW of a constant quantity circulates or is supplied to the substrate processor 9, the pipe system 2 where the DIW flows is assumed to be at a temperature approximate to the temperature of the DIW. Hence, an atmosphere around the pipe system 2 may be cooled to cause dew condensation. Some measure is required to be taken against dew condensation.

From a viewpoint such as the temperature of the DIW to be handled, both a part exposed to the risk of dew condensation and a part not exposed to the risk are present in the processing liquid supplier 1. The part exposed to the risk of dew condensation also includes both a part where attachment of water droplets resulting from dew condensation is not permitted and a part where dew condensation itself causes no problem. Taking a measure for preventing dew condensation uniformly for the entire processing liquid supplier 1 or for the pipe system 2 is not realistic.

In this embodiment, on the basis of the viewpoint of a degree of probability of the occurrence of dew condensation and the viewpoint of a degree to which the occurrence of dew condensation is permitted, the pipe system 2 is divided into a plurality of blocks, and dew condensation management is employed that is responsive to a situation of dew condensation that might occur in each of the blocks. The “dew condensation management” mentioned herein not only means taking a measure for preventing the occurrence of dew condensation simply but is a composite idea including taking a measure for reducing the generated amount of water droplets resulting from dew condensation to a permissible range, and permitting attachment of water droplets and then taking a procedure so as to avoid hindrance to operation due to the water droplets, for example.

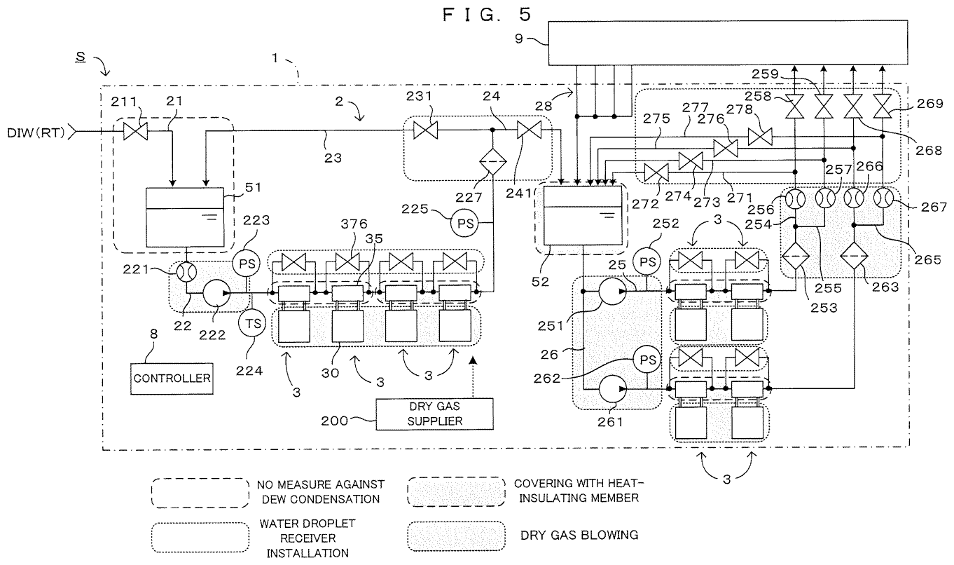

FIG. 5 schematically shows the dew condensation management according to the present embodiment. As shown in FIG. 5, the pipe system 2 is divided into four types of blocks from the two viewpoints including the probability of the occurrence of dew condensation and the necessity of dew condensation prevention. As surrounded by a hollow dashed frame, a first division corresponds to a region where no particular measure against dew condensation is required. This region is a region where the temperature of the processing liquid to be handled is higher than the dew-point temperature Tc and thus no risk of dew condensation is assumed to be caused. For example, the first division covers the primary reservoir tank 51 into which the DIW at room temperature (RT) is supplied from the outside, the two heat exchangers 35A and 35B on the upstream side among the plurality of heat exchangers 35, and the pipes in the vicinity of the primary reservoir tank 51 and the heat exchangers 35A and 35B.

As surrounded by a hollow dotted frame, in a second division, “water droplet receiver installation” is conducted as the dew condensation management. This division corresponds to a region where dew condensation is likely to occur but does not influence the operation of the apparatus. Thus, while the pipe system 2 itself is not subjected to any particular measure, a water droplet receiver having an appropriate configuration is arranged under the pipe system 2 in order to prevent attached water droplets resulting from dew condensation from scattering inside the apparatus. A mechanism for discharging water accumulated in the water droplet receiver may be provided further. In summary, a range where dew condensation is permitted but whereabouts of water droplets are required to be controlled corresponds to the second division. The second division covers pipes, control valves, etc. where the processing liquid at a lower temperature than the dew-point temperature Tc may flow but dew condensation itself is permitted.

A third division and a fourth division correspond to regions where dew condensation is likely to occur and is not permitted. In the third division, dew condensation is prevented by taking a measure of covering a target with a heat-insulating member such as winding the heat-insulating member around a pipe. In the drawing, the third division is indicated by a dashed frame with a gray background. The third division covers the four heat exchangers 35C to 35F on the downstream side among the plurality of heat exchangers 35, and the secondary reservoir tank 52.

The fourth division corresponds to a region where a more reliable action against dew condensation is required or where covering with a heat-insulating member is not proper in terms of a structure. In the drawing, the fourth division is indicated by a dotted frame with a gray background. The fourth division covers the pump 222 and the like, and the cooling medium output part 30. The members belonging to the fourth division receive dry gas that is, for example, clean dry air (CDA) or inert gas such as nitrogen gas blown from a dry gas supplier 200 to operate in response to a control command from the controller 8. For example, the members belonging to the fourth division may be stored in an appropriate housing and the dry gas may be supplied to an internal space of the housing. The dry gas mentioned herein may include low dew-point gas lower in dew-point temperature than the temperature of the processing liquid to be handled.

As described above, in the processing liquid supplier 1 of this embodiment, the pipe system 2 as the flow path of the processing liquid (DIW) is divided into the plurality of blocks mainly from the two viewpoints including the temperature of the DIW to be handled and the necessity of dew condensation prevention. A dew condensation management method optimum for each of the divisions is applied. Taking a measure for preventing dew condensation uniformly on the entire pipe system is not realistic. Like in this embodiment, selecting countermeasure methods individually in units of blocks achieves more effective dew condensation management. The dew condensation management mentioned herein not only includes preventing the occurrence of dew condensation itself but also includes not taking a measure in a part with no probability of dew condensation, and permitting the occurrence of dew condensation itself and then conducting a measure for preventing influence over the operation of the apparatus by dew condensation.

Note that there is a period when the cooled DIW circulates inside the processing liquid supplier 1 without being output as a result of an operation sequence of the substrate processor 9, for example. In this case, the liquid at a lower temperature than the dew-point temperature Tc might flow into a part of the pipe system 2 not subjected to a measure against dew condensation. For example, the DIW at a lower temperature than the dew-point temperature Tc may flow into the heat exchanger 35A or 35B not subjected to a measure against dew condensation.

This case may be handled by taking a measure as follows. Specifically, as shown in FIG. 4B, if the temperature T1 of the DIW input to the heat exchanger 35A is lower than the dew-point temperature Tc, the respective control valves 376 of the heat exchangers 35A and 35B are opened. In response to this, the DIW is caused to flow while bypassing the heat exchangers 35A and 35B. This bypasses cooling by the heat exchangers 35A and 35B to avoid the DIW from being cooled excessively. Furthermore, no dew condensation occurs as restriction is imposed on flow of the DIW at a low temperature into the heat exchangers 35A and 35B not subjected to a measure for preventing dew condensation.

The above control may be applied to each heat exchanger 35 in such a way that, if the temperature of the DIW to be input to each heat exchanger 35 is already lower than a target temperature, the control valve 376 is opened to bypass the corresponding heat exchanger 35. This control may be applied in the same way to the different heat exchanger 35C subjected to the measure for preventing dew condensation. In this case, it is also possible to fulfill the effect of preventing excessive cooling of the DIW. In particular, a target temperature of the DIW becomes more approximate to a freezing point at the heat exchanger 35 at a more subsequent stage, so that the effect of preventing freezing due to excessive cooling has great significance. In an extreme case, if the temperature of the DIW output from the primary reservoir tank 51 is already low sufficiently, all the heat exchangers 35A to 35D might be bypassed.

Contrary to the above, if the temperature of the DIW to circulate is sufficiently higher than a target temperature at an initial stage of cooling immediately after start-up of the apparatus, for example, cooling resulting in small temperature change widths at the heat exchangers 35C, 35D, and the like does not provide much contribution to largely reducing the temperature of the entire DIW in the pipe system 2. For this reason, at the initial stage of the cooling, the downstream heat exchangers 35C and 35D may be bypassed and cooling may be performed only by using the upstream heat exchangers 35A and 35B. In this case, cooling by the heat exchangers 35C and 35D may be performed additionally at a moment when the temperature of the DIW has been reduced by a certain degree. This also applies to the heat exchangers 35E and 35F provided along the pipe 25.

As described above, in the present embodiment, a measure against dew condensation for each part of the apparatus is determined with consideration given to a balance between a degree of probability of the occurrence of dew condensation and a degree of necessity for dew condensation prevention. This makes it possible to achieve the dew condensation management efficiently and effectively without introducing excessive facilities or materials. This contributes to reduction in resource consumption and apparatus cost.

### Second Embodiment

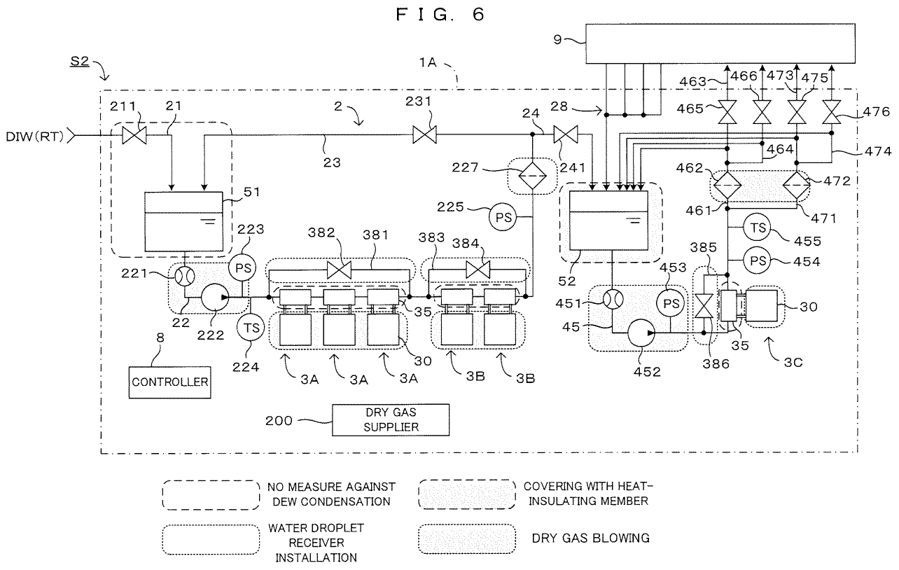

FIG. 6 shows a schematic configuration of a second embodiment of a substrate processing system including a cooling apparatus according to the present invention. The configuration and operation of a substrate processing system S2 according to the second embodiment are basically the same as those of the first embodiment, and differs only in the following point. Here, a structure having the same configuration and fulfilling the same function as that of the first embodiment is given the same sign and description thereof is omitted, and the difference from the first embodiment is mainly described.

The substrate processing system S2 of the second embodiment differs from the substrate processing system S of the first embodiment mainly in the arrangement of the cooling unit. A processing liquid supplier 1A of this embodiment includes a plurality of (in this example, five) cooling units 3A and 3B each having the same configuration as the cooling unit 3 shown in FIG. 2 and connected in series along the pipe 22. Thus, while the cooling unit 3A and the cooling unit 3B have the same configuration, they are given the different signs in order to be distinguished from each other in the following description.

A pipe 381 is provided to collectively bypass three cooling units 3A on the upstream side among the above cooling units, and a control valve 382 is interposed in the pipe 381. A pipe 383 is provided to collectively bypass two cooling units 3B on the downstream side, and a control valve 384 is interposed in the pipe 383. In addition to these units, a pressure sensor, a temperature sensor, a flowmeter, etc. may be provided, as needed.

A configuration on the downstream side with respect to the secondary reservoir tank 52 is also changed. Specifically, a flowmeter 451, a feed pump 452, a pressure sensor 453, the cooling unit 3 (hereinafter denoted by a sign 3C for distinction), a pressure sensor 454, and a temperature sensor 455 are interposed in a pipe 45 connected to the secondary reservoir tank 52. A pipe 385 is provided in such a way as to bypass the cooling unit 3C, and a control valve 386 is interposed in the pipe 385. The pipe 45 branches into two pipes 461 and 471. A filter 462 is interposed in the pipe 461. The pipe 461 further branches into two pipes 463 and 464. A control valve 465 is interposed in the pipe 463, and a control valve 466 is interposed in the pipe 464.

A filter 472 is interposed in the pipe 471. The pipe 471 further branches into two pipes 473 and 474. A control valve 475 is interposed in the pipe 473, and a control valve 476 is interposed in the pipe 474. These four-system pipes 463, 464, 473, and 474 function as feed pipes for feeding the DIW to the substrate processor 9. Pipes 481 to 484 for causing the DIW to flow back into the secondary reservoir tank 52 are connected to the pipes 463, 464, 473, and 474 respectively.

In this embodiment, the three cooling units 3A are, as a whole, handled as one cooling unit, and the two cooling units 3B are, as a whole, handled as one cooling unit. In this regard, this embodiment largely differs from the first embodiment where each cooling unit 3 is controlled individually. However, an idea of temperature regulation is basically the same as that of the first embodiment except that, in bypassing a cooling unit as needed, the bypass is conducted in units of a plurality of cooling units collectively.

Also in FIG. 6, divisions for dew condensation management are further illustrated. The illustration is provided in the same way as in FIG. 5, and the divisions are made on the basis of the common fundamental idea. Specifically, in this embodiment, the first division covers the primary reservoir tank 51, the upstream side with respect to the primary reservoir tank 51, and the three cooling units 3A. No specific measure for preventing dew condensation is taken at these parts.

The second division covers the pipe 381 for bypassing the cooling units 3A collectively, and the pipes 383 and 385, and the control valves 382, 384 and 386 respectively interposed in these pipes. The second division further covers the filter 227. At these parts, no measure is taken for preventing dew condensation directly but only a water droplet receiver for preventing scattering of water droplets is installed as one way of the dew condensation management.

The third division covers the cooling units 3B and 3C, and the secondary reservoir tank 52. An action is taken at these parts by covering the exteriors thereof with heat-insulating members. Meanwhile, the fourth division covers the feed pumps 222 and 452, and the respective cooling medium output parts 30 of the cooling units 3A, 3B and 3C, and the filters 462, 472. These parts receive dry gas blown from the dry gas supplier 200.

In the above configuration, it is also possible to fulfill both temperature regulation of the DIW and dew condensation management on the pipe system 2 by introducing an idea same as that of the first embodiment. In this case, if the temperature of the DIW output from the primary reservoir tank 51 is already reduced sufficiently, the three cooling units 3A may be bypassed collectively by opening the control valve 382. This prevents excessive temperature reduction of the DIW and avoids the occurrence of dew condensation at the cooling unit 3A.

### Modifications

In addition to the two embodiments described above, an embodiment intermediary between these embodiments may be devised. As an example, in the substrate processing system S of the first embodiment shown in FIG. 1, temperature regulation is conducted individually at each of the four cooling units 3 along the pipe 22. These cooling units 3 may be replaced by the cooling units 3A of the second embodiment, the cooling units 3A may be divided into two on the upstream side and two on the downstream side, and each of the two upstream cooling units 3A and the two downstream cooling units 3A may conduct temperature regulation collectively, for example. The number of the cooling units provided in these embodiments is not limited to those illustrated in the drawings but may be increased or reduced, as appropriate.

### Others

As seen from the foregoing, in the above embodiments, the substrate processing systems S and S2 correspond to a “substrate processing apparatus” of the present invention, the processing liquid supplier 1 functions as a “cooling apparatus” and a “cooling part” of the present invention, and the substrate processor 9 functions as a “substrate processor” of the present invention. The pipes 254, 255, 264, 265, 463, 464, 473, and 474 forming connection between these units correspond to a “supply pipe” of the present invention.

Regarding the processing liquid suppliers 1 and 1A of the above embodiments, the cooling units 3 and 3A to 3C function as a “cooler” of the present invention, and the pipe system 2 including these units, the pipe 22, and the like functions as a “flow path former” of the present invention. The heat exchanger 35 (35A to 35F) and the cooling medium output part 30 correspond to a “heat exchanger” and a “cooling medium output part” of the present invention respectively. The heat-insulating member and the water droplet receiver of the above embodiments correspond to a “heat-insulating member” and a “liquid receiver” of the present invention respectively.

Note that the invention is not limited to the above embodiment, and various changes other than the aforementioned ones can be made without departing from the gist of the invention. For example, some examples of the number of the cooling units provided along the pipe system are given in the above description. However, the number of the cooling units or the entire configuration of the pipe system is not limited to that shown above but is determined freely.

In the above embodiments, the cooling unit used for cooling the processing liquid has a configuration where the second cooling medium is cooled using the first cooling medium, and the processing liquid is cooled using the second cooling medium. However, as long as the principles of cooling the processing liquid through heat exchange with the cooling medium, the specific configuration thereof is not limited to the above but is determined freely. The configuration of the heat exchanger is also not limited to that shown in FIGS. 3A to 3C but various configurations are applicable. While the processing liquid supplier 1 of the above embodiment includes the refrigerating circuit 31 and the circulating liquid circuit 33 as the “cooling medium output part” of the present invention, it may alternatively be configured to operate in response to supply of the cooling medium from an external cooling medium supply source configured to output the cooling medium at a constant temperature and a constant flow rate.

Further, for example, while the configuration of the processing liquid supplier 1 of the above embodiment is not divided in terms of its configuration, the upstream side and the downstream side with respect to the pipe 24 as a boundary fulfill different functions. Specifically, structures on the upstream side with respect to the pipe 24 (these structures will be called an “upstream unit” collectively) fulfill the function of reserving the DIW at a temperature approximate to a final temperature and of a quantity sufficient for supply to the substrate processor 9, structures on the downstream side with respect to the pipe 24 (these structures will be called a “downstream unit” collectively) have the function of regulating the DIW reserved in this way to a finally requested temperature and outputting the resultant DIW.

For this reason, the upstream unit and the downstream unit differ from each other in that, while the temperature of the DIW fluctuates largely at the upstream unit, the DIW is at a low temperature and in a stable state at the downstream unit and causes small temperature fluctuation. In view of this, the upstream unit and the downstream unit may be housed in different housings. This allows the upstream unit and the downstream unit to be subjected to dew condensation management independently of each other completely.

Further, in the above embodiments, the processing liquid to be cooled is the DIW. However, the composition or temperature of the processing liquid is not limited to this but is determined freely. For example, the present invention is further applicable to the purpose of cooling each type of chemical, an organic solvent, etc. to be used in processing a substrate. In this case, a material of the pipe is appropriately selectable in response to the property of the processing liquid. If the purity of the processing liquid is not a significant matter, for example, the inner pipe of the heat exchanger may be made of metal from the viewpoint of cooling efficiency. The purpose of use of the processing liquid is also not limited to substrate process but is determined freely.

As has been described above by providing the exemplary specific embodiments, in the cooling apparatus according to the present embodiment, the dew condensation management part may be configured to cover the flow path former in one of the blocks with a heat-insulating member as one way of the dew condensation management. By interposing the heat-insulating member between a member that might become a cause for dew condensation for a low temperature at its surface and outside air, it becomes possible to prevent dew condensation due to condensation of moisture in the outside air.

Further, for example, the dew condensation management part may be configured to blow dry gas to the flow path former in one of the blocks as one way of the dew condensation management. In this configuration, a periphery of a member that might become a cause for dew condensation for a low temperature at its surface is filled with a low dew-point atmosphere, making it possible to prevent dew condensation due to condensation of moisture.

Further, for example, the dew condensation management part may be configured to receive water droplets dripping from the flow path former in one of the blocks using a liquid receiver arranged under the flow path former as one way of the dew condensation management. The occurrence of dew condensation itself might not become a hindrance to a member forming the flow path former when the member fulfills its function. While such a member is not required to be subjected to a measure for preventing dew condensation, dripping of water droplets might influence other members or functional components. Thus, it is preferable to take a measure for preventing scattering of dripping water droplets. By arranging the liquid receiver under dripping water droplets, for example, it becomes possible to prevent scattering of the water droplets.

Further, for example, division into the blocks may be made on the basis of the temperature of the processing liquid flowing through the flow path. As the temperature of the flowing processing liquid becomes lower, an outside air temperature in a periphery is reduced further to increase the probability of the occurrence of dew condensation. Thus, it is rational to select a way of the dew condensation management in response to the temperature of the processing liquid.

In this case, the dew condensation management part may be configured to conduct the dew condensation management on the block where the temperature of the processing liquid is lower than a predetermined value. The probability of dew condensation becomes lower with a higher temperature of the processing liquid. Thus, by taking a measure predominantly on a part where the probability of dew condensation is high, namely, a part where the processing liquid to be handled is at a low temperature, it becomes possible to conduct the dew condensation management effectively in the apparatus as a whole.

Further, for example, the cooler may include the heat exchanger configured to cause the processing liquid to pass therethrough, and the cooling medium output part configured to output the cooling medium to the heat exchanger. In this case, it is desirable to conduct the dew condensation management on each of the heat exchanger and the cooling medium output part. These are significant structures in terms of controlling the temperature of the processing liquid to a desired temperature, and are desirably subjected to the dew condensation management properly, in particular, subjected to measures for preventing dew condensation.

As an example, among the plurality of coolers connected in series, the cooler on a more downstream side in a flow direction of the processing liquid may be configured to output the processing liquid at a lower temperature. In this configuration, the temperature of the processing liquid is reduced stepwise each time the processing liquid passes through the cooler. Thus, a difference is generated in probability of the occurrence of dew condensation between the upstream cooler and the downstream cooler, and this necessarily requires different measures against dew condensation to be taken. The present invention is further effective in such a case.

De-ionized water or pure water is available as the processing liquid of the present invention, for example. In generating cool water by cooling these types of water, if a target temperature for cooling is sufficiently lower than room temperature, which is a temperature approximate to a freezing point of water, for example, a peripheral atmosphere may be cooled to cause dew condensation. The dew condensation management according to the present invention is also effective in such a case. That is, the present invention is useful in generating cool water.

This invention is applicable to every type of technique of cooling a processing liquid. In particular, this invention is preferable in a field where the processing liquid is required to be cooled to a temperature approximate to a freezing point thereof without being frozen.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A cooling apparatus to cool and output a processing liquid, the cooling apparatus comprising:
a flow path former which forms a flow path of the processing liquid, the flow path former including a plurality of coolers each of which reduces a temperature of the processing liquid and a pipe along which the coolers are connected in series with each other; and
a dew condensation management part which is configured to conduct independent dew condensation management on each of a plurality of blocks into which the flow path former is divided.

2. The cooling apparatus according to claim 1, wherein the dew condensation management part covers the flow path former in one of the blocks with a heat-insulating member as the dew condensation management.

3. The cooling apparatus according to claim 1, wherein the dew condensation management part blows dry gas to the flow path former in one of the blocks as the dew condensation management.

4. The cooling apparatus according to claim 1, wherein the dew condensation management part receives water droplets dripping from the flow path former in one of the blocks using a liquid receiver arranged under the flow path former as the dew condensation management.

5. The cooling apparatus according to claim 1, wherein division into the blocks is made on a basis of the temperature of the processing liquid flowing through the flow path.

6. The cooling apparatus according to claim 5, wherein the dew condensation management part is configured to conduct the dew condensation management on the block where the temperature of the processing liquid is lower than a predetermined value.

7. The cooling apparatus according to claim 1, wherein the cooler includes:
a heat exchanger which causes the processing liquid to pass therethrough; and
a cooling medium output part which outputs a cooling medium to the heat exchanger.

8. The cooling apparatus according to claim 7, wherein the dew condensation management is conducted on each of the heat exchanger and the cooling medium output part.

9. The cooling apparatus according to claim 1, wherein among the plurality of coolers connected in series, the cooler on a more downstream side in a flow direction of the processing liquid outputs the processing liquid at a lower temperature.

10. The cooling apparatus according to claim 1, wherein the processing liquid is de-ionized water or pure water.

11. A substrate processing apparatus, comprising:
a cooling part which includes the cooling apparatus according to claim 1;
a substrate processor which processes a substrate using the processing liquid output from the cooling part; and
a supply pipe which supplies the processing liquid from the cooling part to the substrate processor.
